(19) United States
(12) Patent Application Publication
(10) Pub. No.: US 2025/0168986 A1
(43) Pub. Date: May 22, 2025

(54) CIRCUIT BOARD AND METHOD FOR MANUFACTURING MOUNTING BOARD

(71) Applicant: TDK Corporation, Tokyo (JP)

(72) Inventors: Akiko SEKI, Tokyo (JP); Yukari WADA, Tokyo (JP); Hiroyuki UEMATSU, Tokyo (JP); Susumu TANIGUCHI, Tokyo (JP)

(73) Assignee: TDK Corporation, Tokyo (JP)

(21) Appl. No.: 18/952,034

(22) Filed: Nov. 19, 2024

(30) Foreign Application Priority Data
Nov. 21, 2023 (JP) 2023-197367

(51) Int. Cl. H05K 1/18; H05K 3/34

(52) U.S. Cl. CPC H05K 1/181; H05K 3/3494; H05K 2201/10909; H05K 2201/10916

(57) ABSTRACT

A circuit board includes: a substrate having a main surface; a first terminal and a second terminal provided on the main surface of the substrate; and a wall of an insulating material, the wall provided on the main surface of the substrate, in which the wall has at least one groove portion passing through an outer peripheral surface from an inner peripheral surface, the first and second terminals are disposed in a cavity surrounded by the wall, and when a rectangular reference shape having a minimum area circumscribing the inner peripheral surface of the wall is set as viewed from a first direction orthogonal to the main surface of the substrate, at least one terminal of the first and second terminals has a portion disposed on an outer peripheral side from the reference shape via the groove portion.

This application is based upon and claims the benefit of priority from Japanese Patent Application No. 2023-197367, filed on Nov. 21, 2023, the entire contents of which are incorporated herein by reference.

### TECHNICAL FIELD

The present disclosure relates to a circuit board and a method for manufacturing a mounting board.

### BACKGROUND

In recent years, digitalization has progressed, and along with this, the development of a technique for mounting electronic components on substrates is progressing. For example, a technique for mounting a large number of bare chips of semiconductor light emitting elements represented by light emitting diodes (hereinafter, referred to as “LEDs”) used for lighting, display devices, and the like on a wiring substrate has been developed. For example, Japanese Unexamined Patent Publication No. 2006-93523 discloses an invention in which a semiconductor light emitting element is inserted and bonded into a cavity in which a plurality of semiconductor light emitting elements can be easily positioned and arranged. Furthermore, Japanese Unexamined Patent Publication No. 2009-71138 discloses an invention in which an electrode joint portion is provided in a cavity, and an electronic component is inserted into the cavity so as to be joined to the electrode joint portion.

### SUMMARY

A circuit board according to the present disclosure is a circuit board including: a substrate having a main surface; a first terminal and a second terminal provided on the main surface of the substrate; and a wall of an insulating material, the wall provided on the main surface of the substrate, in which the wall has at least one groove portion passing through an outer peripheral surface from an inner peripheral surface, the first and second terminals are disposed in a cavity surrounded by the wall, and when a rectangular reference shape having a minimum area circumscribing the inner peripheral surface of the wall is set as viewed from a first direction orthogonal to the main surface of the substrate, at least one terminal of the first and second terminals has a portion disposed on an outer peripheral side from the reference shape via the groove portion.

### BRIEF DESCRIPTION OF THE DRAWINGS

FIG. 1 is a schematic cross-sectional view illustrating a mounting board including a circuit board according to an embodiment of the present disclosure;

FIG. 2 is a schematic cross-sectional view illustrating a circuit board according to an embodiment of the present disclosure;

FIG. 3 is a plan view of the circuit board;

FIGS. 4A and 4B are views of a wall-frame portion as viewed from a thickness direction;

FIGS. 5A to 5C are schematic cross-sectional views illustrating a method for manufacturing a circuit board and a mounting board;

FIG. 6 is a schematic cross-sectional view illustrating the method for manufacturing a circuit board and a mounting board;

FIGS. 7A to 7F are schematic cross-sectional views illustrating a method for manufacturing a wall portion;

FIG. 8 is a schematic cross-sectional view illustrating a circuit board according to a comparative example;

FIG. 9 is a schematic cross-sectional view illustrating the circuit board according to the comparative example;

FIGS. 10A and 10B are conceptual diagrams illustrating functions and effects of a comparative example and an embodiment;

FIG. 11 is a view illustrating a circuit board according to a modification;

FIG. 12 is a view illustrating a circuit board according to a modification;

FIG. 13 is a view illustrating a circuit board according to a modification;

FIG. 14 is a view illustrating a circuit board according to a modification; and

FIG. 15 is a view illustrating a circuit board according to a modification.

### DETAILED DESCRIPTION

In the following description, with reference to the drawings, the same reference numbers are assigned to the same components or to similar components having the same function, and overlapping description is omitted.

It is to be understood that not all aspects, advantages and features described herein may necessarily be achieved by, or included in, any one particular example. Indeed, having described and illustrated various examples herein, it should be apparent that other examples may be modified in arrangement and detail.

Here, in the structure as in Japanese Unexamined Patent Publication No. 2006-93523, the electronic component moves in the cavity, and for example, a problem arises in that the directions of elements become uneven in the LED element or the like. In the configuration as in Japanese Unexamined Patent Publication No. 2009-71138, when the electronic component is miniaturized, the cavity is also miniaturized accordingly. At this time, it is necessary to reduce the terminal in size in the cavity. However, it is difficult to form a pattern having a small size with high positional accuracy due to problems such as resolution limits of a resist and an exposure device, and there is a problem such as a decrease in yield due to a decrease in quality caused by dimensional variations or the like.

An object of the present disclosure is to provide a circuit board capable of suppressing a decrease in quality and accurately positioning an electronic component, and a method for manufacturing a mounting board.

A method for manufacturing a mounting board according to the present disclosure is a method for manufacturing a mounting board by mounting an electronic component on the above-described circuit board to manufacture a mounting board, in which a filling material is disposed on the substrate, the electronic component is disposed, and then the electronic component may be bonded to the terminal by using a pressurization reflow device.

According to the present disclosure, it is possible to provide a circuit board capable of suppressing a decrease in quality and accurately positioning an electronic component, and a method for manufacturing a mounting board.

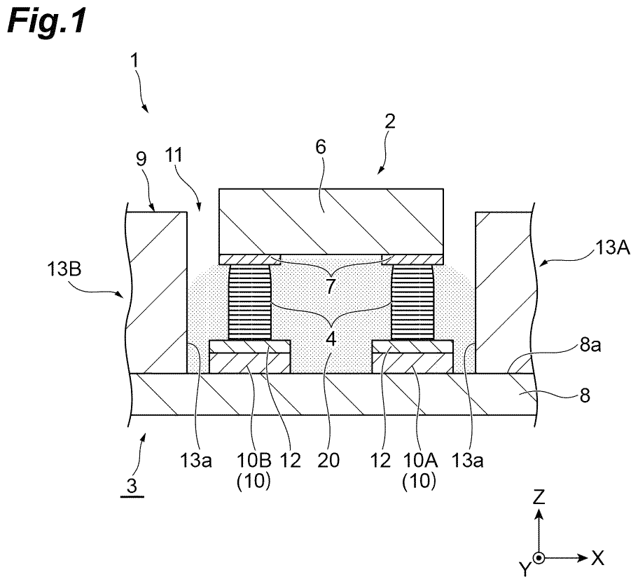

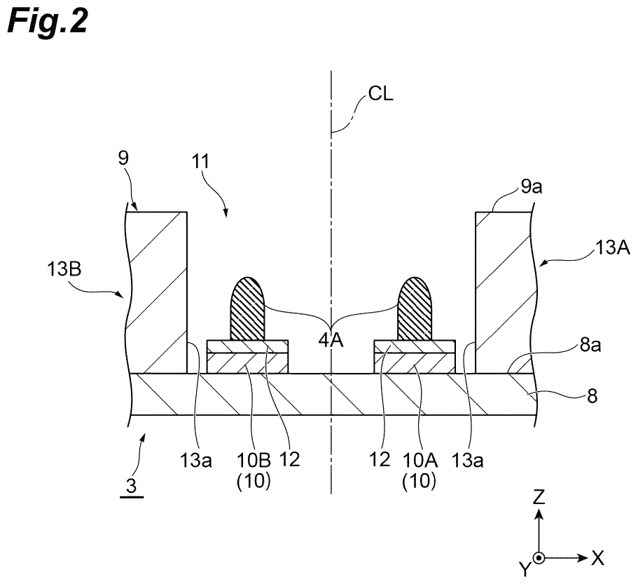

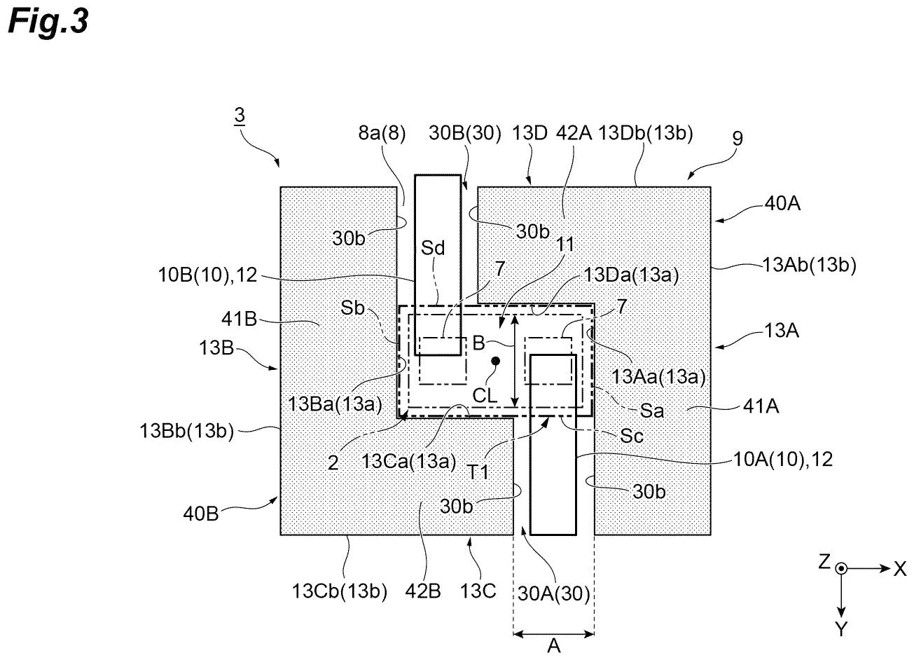

Referring to FIGS. 1 to 3, a circuit board 3 according to an embodiment of the present disclosure will be described. FIG. 1 is a schematic cross-sectional view illustrating a mounting board 1 including the circuit board 3 according to an embodiment of the present disclosure. FIG. 2 is a schematic cross-sectional view illustrating the circuit board 3 according to an embodiment of the present disclosure. FIG. 3 is a plan view of the circuit board 3.

As illustrated in FIG. 1, the mounting board 1 includes an electronic component 2 and the circuit board 3. The mounting board 1 is configured by mounting the electronic component 2 on the circuit board 3 via a bonding material 4.

The electronic component 2 includes a body portion 6 and a pair of terminals 7. The body portion 6 is a member for exhibiting a function as the electronic component 2. The terminals 7 are metal portions formed on a main surface of the body portion 6. As a material for the terminals 7, a metal such as Cu, Ti, Au, Ni, Sn, Bi, P, B, In, Ag, Zn, Pd, Mo, Pt, Cr, and an alloy selected from at least two of them, or the like is adopted. The electronic component 2 is configured of, for example, a micro LED, or the like. The micro LED is a component emitting light according to an input from the circuit board 3.

The circuit board 3 includes a substrate 8, a wall 9, and a pair of terminals 10 (a first terminal and a second terminal). The substrate 8 is a flat plate-shaped body portion of the circuit board 3. The substrate 8 has a main surface 8a. The substrate 8 may employ a printed circuit board for mounting each conductor pattern and each electronic component on the main surface 8a of the circuit board 3. As a material for the substrate 8, a known resin material or ceramic material used for a printed board may be adopted. Note that the following description may be made using XYZ coordinates set for the circuit board 3. An X-axis direction (second direction) is a direction parallel to the main surface 8a of the substrate 8, a Y-axis direction (third direction) is a direction parallel to the main surface 8a of the substrate 8 and orthogonal to the X-axis direction, and a Z-axis direction (first direction) is a direction orthogonal to the main surface 8a of the substrate 8.

The wall 9 of an insulating material is provided on the main surface 8a of the substrate 8. The wall 9 is a member formed of an insulating material. The wall 9 protrudes from the substrate 8 toward the positive side in the Z-axis direction. As illustrated in FIG. 3, in the present embodiment, the wall 9 has wall-frame portions 13A, 13B, 13C, and 13D provided in four directions. The wall-frame portions 13A and 13B face each other in a state of being separated from each other in the X-axis direction, and extend in parallel to the Y-axis direction. The wall-frame portion 13A is disposed on the positive side in the X-axis direction, and the wall-frame portion 13B is disposed on the negative side. The wall-frame portions 13C and 13D face each other in a state of being separated from each other in the Y-axis direction, and extend in parallel to the X-axis direction. The wall-frame portion 13C is disposed on the positive side in the Y-axis direction, and the wall-frame portion 13D is disposed on the negative side. The wall-frame portion 13A connects end portions of the wall-frame portions 13C and 13D on the positive side in the X-axis direction to each other. The wall-frame portion 13B connects the end portions of the wall-frame portions 13C and 13D on the negative side in the X-axis direction to each other. As a result, the wall 9 has a rectangular frame-shaped structure as viewed in the Z-axis direction. The wall-frame portions 13A and 13B constitute short sides, and the wall-frame portions 13C and 13D constitute long sides. Note that, the dimension is not particularly limited, but the dimension in the Y-axis direction of the wall-frame portions 13A and 13B may be set to 10 μm to 60 μm. The dimension in the X-axis direction of the wall-frame portions 13C and 13D may be set to 15 μm to 70 μm. The dimension of the short side of the inner peripheral surface inside the wall 9 may be set to 8 μm or more and 44 μm or less. The dimension of the long side of the inner peripheral surface inside the wall 9 may be 15 μm or more and 68 μm or less. The dimension of the short side of the inner peripheral surface inside the wall 9 is the dimension in the Y-axis direction of an inner peripheral surface 13a of the wall-frame portion 13C and an inner peripheral surface 13a of the wall-frame portion 13D. The dimension of the long side of the inner peripheral surface inside the wall 9 is the dimension in the X-axis direction of an inner peripheral surface 13a of the wall-frame portion 13A and an inner peripheral surface 13a of the wall-frame portion 13B. As a material for the wall 9, for example, a resin material such as an epoxy resin, an acrylic resin, a phenol resin, a melamine resin, a urea resin, or an alkyd resin is adopted. Particularly preferably, as a material for the wall 9, an epoxy resin or an acrylic resin is adopted.

As illustrated in FIGS. 1 to 3, the terminals 10 are metal portions provided on the main surface 8a of the substrate 8. As a material for the terminals 10, Ni, Cu, Ti, Cr, Al, Mo, Pt, Au, an alloy selected from at least two of them, or the like is adopted. A conductive film 12 is formed on an upper surface of the terminal 10. As a material for the conductive film 12, a film of Ti, Cu, Ni, Al, Mo, Cr, Ag, or the like, a film in which metal particles and a binder are mixed, or the like is adopted.

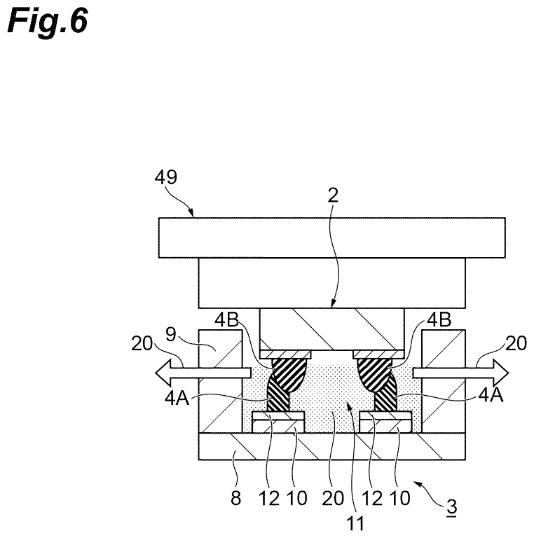

The bonding material 4 is a member bonding the terminals 7 of the electronic component 2 and the terminals 10 of the circuit board 3. The bonding material 4 is configured by thermally bonding and integrating a bonding material 4A on the circuit board 3 side and a bonding material 4B on the electronic component 2 side (see FIG. 6). The bonding material 4 may contain Sn or may be made of an alloy containing Sn. However, the bonding material 4 is not necessarily limited to one containing Sn. The bonding material 4 may be made of an alloy containing, in addition to Sn, an element lowering a melting point of Sn. Examples of the element lowering a melting point of Sn include Bi. The bonding material 4 functions as solder. Thus, the terminals 10, the conductive film 12, the bonding material 4, and the terminals 7 are stacked in this order from the upper surface of the substrate 8 between the substrate 8 and the body portion 6. Note that, solder bonding is performed at that location after the terminals 10, the conductive film 12, the bonding material 4, and the terminals 7 are stacked. Therefore, after the solder bonding, a structure in which the metals of the terminals 10, the conductive film 12, the bonding material 4, and the terminals 7 are melted and diffused is formed. The structure after such solder bonding may be a structure containing a brittle intermetallic compound (IMC). When an intermetallic compound having a brittle structure is present, it is likely to be fractured due to stress from the outside, and thus reliability tends to decrease. Therefore, the effect of protecting the electronic component 2 is achieved by surrounding the electronic component 2 with the wall 9.

A cavity 11 is formed in the wall 9. The cavity 11 is configured by a through hole passing through the wall 9 in the Z-axis direction. Thus, the upper surface of the substrate 8 is exposed on the bottom side of the cavity 11. The cavity 11 has a rectangular shape as viewed in the Z-axis direction (see FIG. 3). The terminals 7, the terminals 10, the conductive film 12, and the bonding material 4 are disposed in the cavity 11 surrounded by the wall 9 so as to be surrounded by the wall 9. Slight gaps are formed between the inner peripheral surfaces 13a of the four wall-frame portions 13A, 13B, 13C, and 13D constituting the cavity 11 and the terminals 7, the terminals 10, the conductive film 12, and the bonding material 4.

A filling material 20 is disposed between the electronic component 2 and the bonding material 4, and the wall 9 in the cavity 11. Thus, the electronic component 2 can be made difficult to be separated from the circuit board 3 by being supported by the filling material 20. Furthermore, a force applied to the electronic component 2, the bonding material 4, and the terminals 7 and 10 is relaxed, and reliability can be improved. As a material for the filling material 20, for example, an epoxy resin, an acrylic resin, a phenol resin, a melamine resin, a urea resin, an alkyd resin, a mixture thereof, or a mixture of the above-described resin materials with SiOx, ceramics, and the like is adopted. Particularly preferably, as a material for the filling material 20, an epoxy resin or an acrylic resin is adopted. A viscosity of the filling material 20 at the time of filling may be 1 Pa to 20 Pa and may be further 5 Pa to 10 Pa.

As illustrated in FIG. 2, the circuit board 3 has a configuration in which the electronic component 2 and the filling material 20 are removed from the mounting board 1 illustrated in FIG. 1. Note that, in the circuit board 3, the bonding material 4A containing a metal element is disposed above the terminals 10 (on the upper surface of the conductive film 12). The circuit board 3 includes the bonding material 4A (first bonding material) disposed on a terminal 10A on the positive side in the X-axis direction and the bonding material 4A (second bonding material) disposed on a terminal 10B on the negative side in the X-axis direction. As described above, these bonding materials 4A constitute a part of the bonding material 4 in the previous stage in which the electronic component 2 and the mounting board 1 are thermally bonded. In the state of the circuit board 3, the pair of terminals 10, the conductive film 12, and the bonding material 4A are disposed inside the wall 9 formed of an insulator.

As illustrated in FIG. 3, the wall 9 has at least one groove portion 30 passing through an outer peripheral surface 13b from the inner peripheral surface 13a. In the present embodiment, the wall 9 has one groove portion 30A in the wall-frame portion 13C and one groove portion 30B in the wall-frame portion 13D. For the wall-frame portions 13C and 13D, the Y-axis direction is the thickness direction. Therefore, the groove portions 30A and 30B of the wall-frame portions 13C and 13D extend in the Y-axis direction and pass through the wall-frame portions 13C and 13D. Note that, the groove portion 30 may be formed in at least one of the wall-frame portions 13A, 13B, 13C, and 13D. Furthermore, a plurality of groove portions 30 may be formed in any one of the wall-frame portions 13A, 13B, 13C, and 13D. Furthermore, the groove portions 30 may be formed at a corner portion of each of the wall-frame portions 13A, 13B, 13C, and 13D (details will be described later).

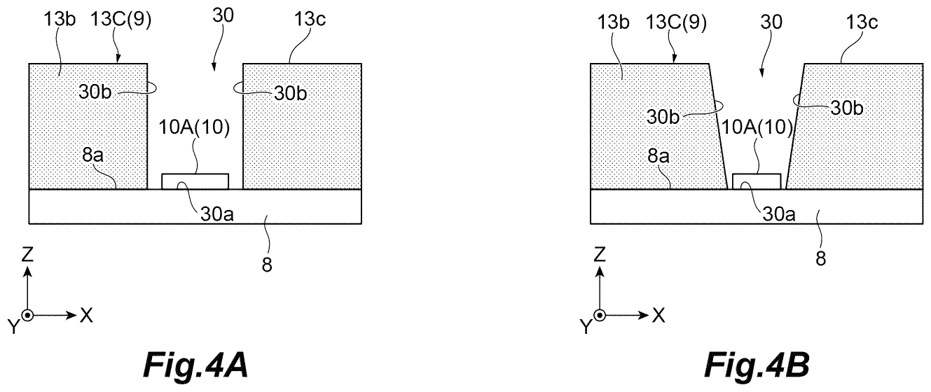

Next, referring to FIGS. 4A and 4B, a configuration of the wall-frame portion 13C as viewed in the thickness direction will be described. FIG. 4A is a view of the wall-frame portion 13C as viewed in the Y-axis direction which is the thickness direction. Note that, although the wall-frame portion 13C is illustrated in FIGS. 4A and 4B, the same description holds for the other wall-frame portion 13D. As illustrated in FIG. 4A, as viewed in the Y-axis direction which is the thickness direction of the wall-frame portion 13C, the groove portion 30 extends from a distal end portion 13c in a height direction (the Z-axis direction in present embodiment) of the wall-frame portion 13C toward the substrate 8 side (the negative side in the Z-axis direction). The groove portion 30 has a bottom surface 30a and a pair of side surfaces 30b. The bottom surface 30a is formed on the negative side in the Z-axis direction with respect to the distal end portion 13c. The pair of side surfaces 30b extends from both end portions of the bottom surface 30a in the X-axis direction to the distal end portion 13c. In an example illustrated in FIG. 4A, the groove portion 30 extends to the main surface 8a of the substrate 8.

As illustrated in FIG. 4B, the width of the groove portion 30 in the X-axis direction, which is the width direction, is larger on the distal end portion 13c side than on the bottom surface 30a side. The width of the groove portion 30 at the distal end portion 13c is larger than the width of the groove portion 30 at the bottom surface 30a. In an example illustrated in FIG. 4B, the groove portion 30 is largely opened in the X-axis direction toward the distal end portion 13c side. The pair of side surfaces 30b is inclined such that a distance between the side surfaces increases toward the positive side in the Z-axis direction.

Note that the width of the groove portion 30 is not particularly limited as long as it is a dimension that is not excessively small in order to discharge the excessive filling material 20. For example, the width of the groove portion 30 may be 1 μm or more, and may be 4 μm or more. Note that the wall-frame portion 13 may be large enough to position the electronic component 2, and the width of the groove portion 30 may be set to be large.

As illustrated in FIG. 3, the wall 9 has an L-shaped frame 40A (first frame) and an L-shaped frame 40B (second frame). The frames 40A and 40B are configured to be rotationally symmetric with respect to a central axis CL of the cavity 11. The central axis CL is set by an imaginary line extending in a direction orthogonal to the substrate 8 with respect to a central position of a rectangular reference shape T1 described later (see also FIG. 2). The term “rotationally symmetric” means that when one shape is rotated by 180° around the central axis CL, the one shape has a relationship of matching with the other shape. The frames 40A and 40B are formed by dividing the wall 9 having a rectangular annular shape rotationally symmetric with respect to the central axis CL by a pair of groove portions 30A and 30B. Therefore, the groove portions 30A and 30B are also configured to be rotationally symmetric with respect to the central axis CL.

The groove portion 30A formed in the wall-frame portion 13C is formed on the positive side in the X-axis direction with respect to the central axis CL. The side surface 30b of the groove portion 30A on the positive side in the X-axis direction is disposed at the same position in the X-axis direction and extends in the Y-axis direction so as to be a surface continuous with an inner peripheral surface 13Aa of the wall-frame portion 13A. The side surface 30b of the groove portion 30A on the negative side in the X-axis direction is disposed at a position spaced apart from the inner peripheral surface 13Aa toward the negative side in the X-axis direction. In FIG. 3, the side surface 30b of the groove portion 30A on the negative side in the X-axis direction is disposed at a position on the positive side in the X-axis direction with respect to the central axis CL, but may be disposed at the same position as the central axis CL or at a position on the negative side in the X-axis direction.

The groove portion 30B formed in the wall-frame portion 13D is formed on the negative side in the X-axis direction with respect to the central axis CL. The side surface 30b of the groove portion 30B on the negative side in the X-axis direction is disposed at the same position in the X-axis direction and extends in the Y-axis direction so as to be a surface continuous with an inner peripheral surface 13Ba of the wall-frame portion 13B. The side surface 30b of the groove portion 30B on the positive side in the X-axis direction is disposed at a position spaced apart from the inner peripheral surface 13Ba toward the positive side in the X-axis direction. In FIG. 3, the side surface 30b of the groove portion 30B on the positive side in the X-axis direction is disposed at a position on the negative side in the X-axis direction with respect to the central axis CL, but may be disposed at the same position as the central axis CL or at a position on the positive side in the X-axis direction.

The frame 40A has a first side portion 41A extending in the Y-axis direction and a second side portion 42A extending in the X-axis direction. The first side portion 41A is configured of the wall-frame portion 13A and a pa of the wall-frame portion 13C. A part of the wall-frame portion 13C is a portion of the wall-frame portion 13C on the positive side in the X-axis direction with respect to the groove portion 30A. The second side portion 42A is configured of a part of the wall-frame portion 13D. A part of the wall-frame portion 13D is a portion of the wall-frame portion 13D on the positive side in the X-axis direction with respect to the groove portion 30B.

The frame 40B has a first side portion 41B extending in the Y-axis direction and a second side portion 42B extending in the X-axis direction. The first side portion 41B is configured of the wall-frame portion 13B and a pa of the wall-frame portion 13D. A part of the wall-frame portion 13D is a portion of the wall-frame portion 13D on the negative side in the X-axis direction with respect to the groove portion 30B. The second side portion 42B is configured of a part of the wall-frame portion 13C. A part of the wall-frame portion 13C is a portion of the wall-frame portion 13C on the negative side in the X-axis direction with respect to the groove portion 30A.

Here, the reference shape T1 having a rectangular annular shape is set for the cavity 11. The reference shape T1 is an imaginary shape having a minimum area circumscribing the inner peripheral surface 13a of the wall 9 as viewed from the height direction (Z-axis direction). The reference shape T1 is indicated by a dash-dotted line in FIG. 3. In the present embodiment, the reference shape T1 has a rectangular shape whose longitudinal direction is the X-axis direction.

The reference shape T1 has a pair of long side portions Sc and Sd extending in the X-axis direction which is the longitudinal direction. The pair of long side portions Sc and Sd is separated from each other in the Y-axis direction. The long side portion Sc on the positive side in the Y-axis direction has a line segment drawn by a part of an inner peripheral surface 13Ca of the wall-frame portion 13C and a line segment crossing the groove portion 30A in the X-axis direction, which is an imaginary extension line of the inner peripheral surface 13Ca. The long side portion Sd on the negative side in the Y-axis direction has a line segment drawn by a part of an inner peripheral surface 13Da of the wall-frame portion 13D and a line segment crossing the groove portion 30B in the X-axis direction, which is an imaginary extension line of the inner peripheral surface 13Da.

The reference shape T1 has a pair of short side portions Sa and Sb extending in the Y-axis direction which is the lateral direction. The pair of short side portions Sa and Sb is separated from each other in the X-axis direction. The short side portion Sa on the positive side in the X-axis direction has a line segment drawn by the inner peripheral surface 13Aa of the wall-frame portion 13A. The short side portion Sb on the negative side in the X-axis direction has a line segment drawn by the inner peripheral surface 13Ba of the wall-frame portion 13B.

The electronic component 2 (indicated by an imaginary line) disposed in the cavity 11 is positioned by the pair of frames 40A and 40B. The frames 40A and 40B position the electronic component 2 with each of the inner peripheral surfaces 13Aa, 13Ba, 13Ca, and 13Da as a restriction surface. Therefore, the electronic component 2 inserted into the cavity 11 is automatically positioned on each of the inner peripheral surfaces 13Aa, 13Ba, 13Ca, and 13Da, and is disposed so as to fall within a range of the reference shape T1. That is, the electronic component 2 is positioned so as not to protrude from the reference shape T1 to the outer peripheral side. When the central axis of the electronic component 2 is accurately disposed so as to coincide with the central axis CL of the cavity 11, a gap between the outer peripheral surface of the electronic component 2 and each of the inner peripheral surfaces 13Aa, 13Ba, 13Ca, and 13Da of the wall 9 is set to about 0 μm to 5.0 μm. When the gap is too large, the positioning accuracy is deteriorated, and when the gap is too small, it is difficult to insert the electronic component 2 into the cavity 11. By setting the gap within the above range, positioning can be easily and accurately performed.

With respect to the frames 40A and 40B and the cavity 11 as described above, the pair of terminals 10 is formed on the main surface 8a of the substrate 8. The pair of terminals 10 has a rotationally symmetric configuration around the central axis CL. The pair of terminals 10 has a portion disposed on the outer peripheral side from the reference shape T1. The terminal 10A (first terminal) is disposed on the positive side in the X-axis direction with respect to the central axis CL. The terminal 10A extends toward the positive side in the Y-axis direction from a location where the terminals 7 of the electronic component 2 are disposed in the reference shape T1. The terminal 10A extends toward the outer peripheral side (the positive side in the Y-axis direction) with respect to the long side portion Sc of the reference shape T1 and is disposed in the groove portion 30A. In the groove portion 30A, the terminal 10A is formed on the main surface 8a of the substrate 8 (see FIGS. 4A and 4B) constituting the bottom surface 30a of the groove portion 30A. In the groove portion 30A, the terminal 10A extends to the position of an outer peripheral surface 13Cb, but the position to which the terminal extends with respect to the groove portion 30A is not particularly limited. In the present embodiment, the terminal 10A has a portion disposed on the outer peripheral side from only one long side portion Sc (the long side portion on the positive side in the Y-axis direction) of the rectangular reference shape T1.

The terminal 10B (second terminal) is disposed on the negative side in the X-axis direction with respect to the central axis CL. The terminal 10B extends toward the negative side in the Y-axis direction from a location where the terminals 7 of the electronic component 2 are disposed in the reference shape T1. The terminal 10B extends toward the outer peripheral side (the negative side in the Y-axis direction) with respect to the long side portion Sd of the reference shape T1 and is disposed in the groove portion 30B. In the groove portion 30B, the terminal 10B is formed on the main surface 8a of the substrate 8 (see FIGS. 4A and 4B) constituting the bottom surface 30a of the groove portion 30B. In the groove portion 30B, the terminal 10B extends to the position of an outer peripheral surface 13Db, but the position to which the terminal extends with respect to the groove portion 30B is not particularly limited. In the present embodiment, the terminal 10B has a portion disposed on the outer peripheral side from only one long side portion Sd (the long side portion on the negative side in the Y-axis direction) of the rectangular reference shape T1.

A minimum aperture dimension A of the groove portions 30A and 30B is equal to or less than a dimension B of the short side of the electronic component 2 that can be mounted on the terminals 10A and 10B. In the present embodiment, the groove portions 30A and 30B extend from the inner peripheral surfaces 13Ca and 13Da with a constant width in the Y-axis direction, and open at the outer peripheral surfaces 13Cb and 13Db. Therefore, the width dimension itself of the groove portions 30A and 30B becomes the minimum aperture dimension A of the groove portions 30A and 30B.

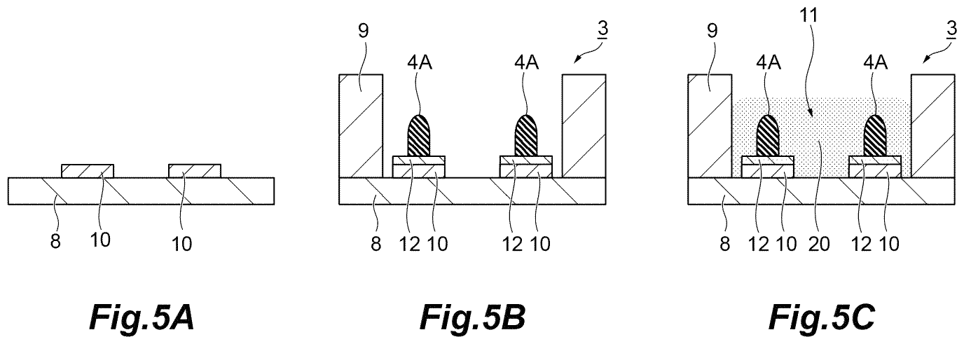

Referring to FIGS. 5A to 5C and 6, a method for manufacturing the circuit board 3 and the mounting board 1 will be described. First, as illustrated in FIG. 5A, the terminals 10 are formed on the upper surface of the substrate 8. Next, as illustrated in FIG. 5B, the wall 9 is formed on the substrate 8. Thus, the circuit board 3 is completed. In FIG. 5B, the conductive film 12 and the bonding material 4A are formed on the upper surface of the terminal 10. Next, as illustrated in FIG. 5C, the filling material 20 is disposed on the substrate 8 by filling the cavity 11 with the filling material 20. Then, the electronic component 2 is held by a holding member, and the electronic component 2 is mounted in the cavity 11. Next, as illustrated in FIG. 6, the electronic component 2 is pressed into the cavity 11 by a pressurization reflow device 49 with respect to the electronic component 2, and the bonding material 4A and the bonding material 4B are brought into contact with each other inside the filling material 20. At this time, a part of the filling material 20 is pushed out to the groove portion 30 (see FIG. 3). Next, the bonding material 4B of the electronic component 2 and the bonding material 4A of the substrate 8 are bonded by heating. Thus, the mounting board 1 is completed. Note that, in this process, the electronic component 2 is positioned in the cavity 11 by the frames 40A and 40B (see FIG. 3).

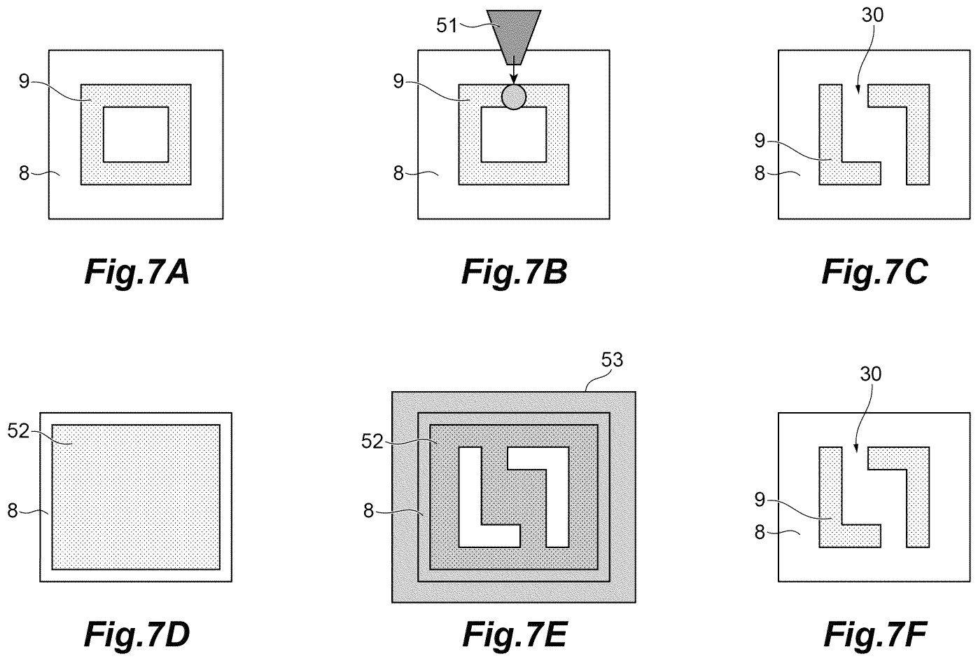

Next, referring to FIGS. 7A to 7F, a method of forming the wall 9 having the groove portion 30 will be described. First, as illustrated in FIG. 7A, the wall 9 is formed on the substrate 8. Next, as illustrated in FIG. 7B, a part of the wall 9 is processed by irradiating the wall 9 with a laser beam by a laser device 51. As a result, as illustrated in FIG. 7C, the groove portion 30 is formed in the wall 9.

Alternatively, as illustrated in FIG. 7D, a resist 52 is formed on the substrate 8. Next, as illustrated in FIG. 7E, exposure is performed using a glass mask 53 having a pattern corresponding to the shape of the wall 9 having the groove portion 30. As illustrated in FIG. 7F, the exposed resist 52 is developed to form the wall 9 having the groove portion 30.

Next, functions and effects of the circuit board 3 and the method for manufacturing the mounting board 1 according to the present embodiment will be described.

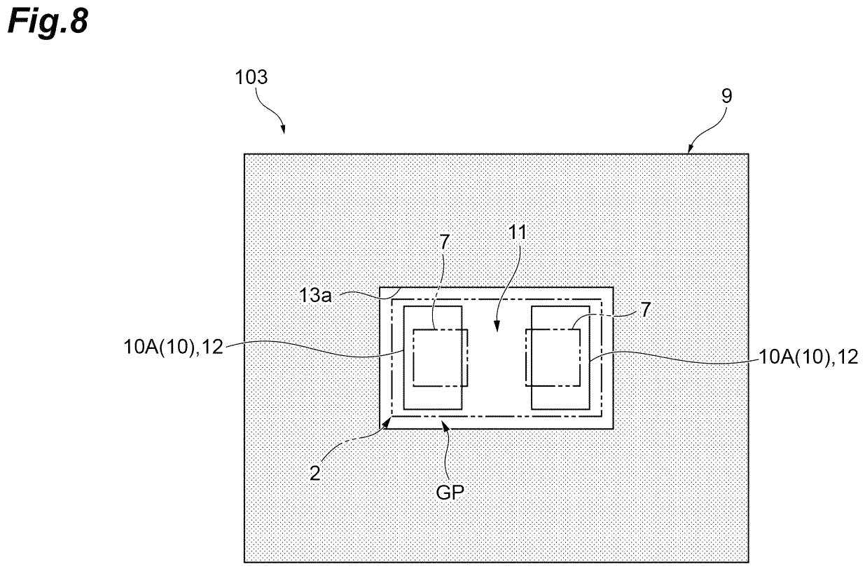

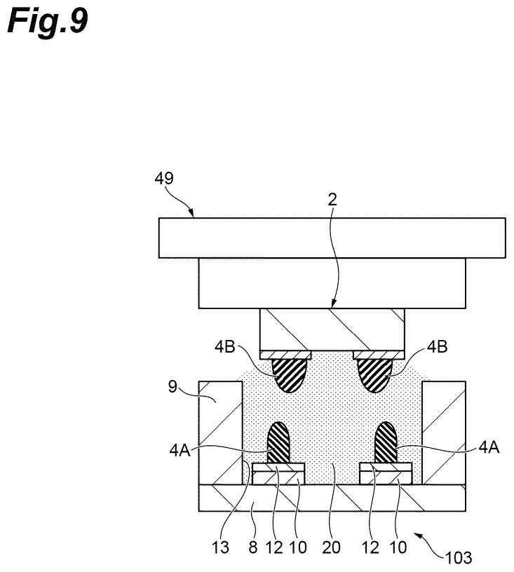

First, a circuit board 103 according to a comparative example will be described with reference to FIGS. 8 and 9. As illustrated in FIG. 8, the wall 9 of the circuit board 103 does not have the groove portion 30 described above. When the electronic component 2 is miniaturized, the cavity 11 is also miniaturized accordingly. At this time, since the terminal 10 has to be disposed within a range surrounded by the inner peripheral surface 13a of the wall 9, it is also necessary to reduce the terminal 10 in size in the cavity 11. However, it was difficult to form a pattern having a small size with high positional accuracy due to problems such as resolution limits of a resist and an exposure device, and there was a problem such as a decrease in yield due to a decrease in quality caused by dimensional variations or the like. Furthermore, for example, when the wall 9 and the terminal 10 overlap each other, a defect occurs in the formation pattern of the terminal 10. When the wall 9 and the terminal 10 cannot be overlapped with each other as described above, a gap GP between the inner peripheral surface 13a and the terminal 10 has to have a dimension in consideration of alignment accuracy and dimensional variations of an exposure device. In this case, the cavity 11 becomes large, and the positioning accuracy of the electronic component 2 is deteriorated.

Furthermore, as illustrated in FIG. 9, after the filling material 20 is filled in the wall 9, when the electronic component 2 is mounted in the wall 9 using a holding member and the electronic component 2 is pushed by a pressurization reflow device, the electronic component 2 cannot be sufficiently pushed due to the influence of the excessive filling material 20. In this case, reflow is performed in a state where the bonding material 4B of the electronic component 2 and the bonding material 4A of the circuit board 3 remain separated from each other, and there is a possibility that a connection failure occurs between the bonding material 4A of the circuit board 3 and the electronic component 2.

On the other hand, in the circuit board 3 according to the present embodiment, the terminal 10A (first terminal) and the terminal 10B (second terminal) are disposed in the cavity 11. Therefore, when the electronic component 2 is mounted on the circuit board 3, the electronic component 2 is inserted into the cavity 11 to be bonded to the terminals 10A and 10B via the bonding material 4A. At this time, the electronic component 2 is positioned by the inner peripheral surface 13a of the wall 9. Therefore, when the electronic component 2 is miniaturized, the electronic component 2 can be accurately positioned by reducing the size of the cavity 11. In a case where the rectangular reference shape T1 having the minimum area circumscribing the inner peripheral surface 13a of the wall 9 as viewed from the Z-axis direction (first direction) is set, when the terminals 10A and 10B are to be accommodated within the range of the reference shape T1, it is necessary to reduce the terminals 10A and 10B in size as the cavity 11 is downsized as described above. On the other hand, in the circuit board 3 according to the present embodiment, at least one groove portion 30 passing through the outer peripheral surface 13b from the inner peripheral surface 13a is formed in the wall 9. In this manner, by providing the groove portion 30 in the wall 9, the groove portion 30 can be secured as a space for disposing the terminals 10A and 10B. At least one terminal of the terminals 10A and 10B has a portion disposed on the outer peripheral side from the reference shape T1 via the groove portion 30. Therefore, by also using the space on the outer peripheral side of the reference shape T1, it is possible to suppress at least one terminal of the terminals 10A and 10B from becoming excessively small. As a result, the difficulty of pattern formation of the terminals 10A and 10B can be reduced, and the quality can be stabilized. As described above, it is possible to suppress a decrease in quality and accurately position the electronic component 2.

Furthermore, the wall 9 has at least one groove portion 30 passing through the outer peripheral surface 13b from the inner peripheral surface 13a. In this case, when the electronic component 2 is mounted on the circuit board 3 by disposing the filling material 20 in the cavity 11, mounting the electronic component using a holding member, and pressing and heating the electronic component 2 into the cavity 11 using the pressurization reflow device to bond the electronic component 2 to the circuit board 3, the excessive filling material 20 can be discharged to the outside of the wall 9 through the groove portion 30. As a result, the electronic component 2 can be sufficiently pushed into the cavity 11 in a pressurizing step using the pressurization reflow device and brought into contact with the bonding material 4.

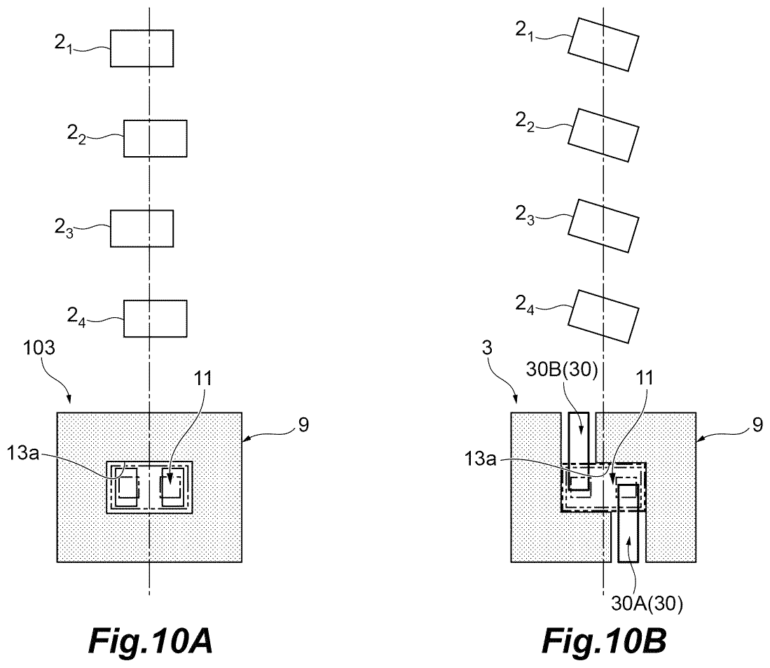

The wall 9 may have the L-shaped frame 40A (first frame) and the L-shaped frame 40B (second frame), and the frames 40A and 40B may be configured to be rotationally symmetric with respect to the central axis CL of the cavity 11. In this case, by using the L-shaped frames 40A and 40B that are rotationally symmetric, the electronic component 2 can be positioned in a well-balanced manner from four directions. Furthermore, as illustrated in FIG. 10A, in the circuit board 103 according to the comparative example, the inner peripheral surface 13a surrounds the entire circumference in a state where the cavity 11 is larger than the electronic component 2. In this case, when a plurality of electronic components 2 are positioned in each cavity 11, each electronic component 2 is displaced in a non-uniform direction. On the other hand, in the circuit board 3 according to the present embodiment, by using the rotationally symmetric frames 40A and 40B, even if positional displacement of the electronic component 2 occurs in the cavity 11, the rotation direction of the positional displacement can be made uniform. In this case, when the electronic component 2 emits light, it is possible to suppress the non-uniformity of the entire light emitting position as compared with a case where the electronic component 2 is non-uniformly displaced as in the comparative example. Furthermore, by making the direction of the positional displacement uniform, it is easy to detect an NG product in the inspection.

The minimum aperture dimension A of the groove portion 30 may be equal to or less than the dimension B of the short side of the electronic component 2 that can be mounted on the terminals 10A and 10B. In this case, even when rotation or deviation of the electronic component 2 occurs in the cavity 11, movement from the groove portion 30 to the outer peripheral side can be suppressed and the electronic component 2 can be kept in the cavity 11.

At least one terminal of the terminals 10A and 10B may have a portion disposed on the outer peripheral side from only one side portion of the rectangular reference shape T1. In this case, the size of the groove portion 30 can be reduced, and the rotation or deviation of the electronic component 2 in the cavity 11 can be suppressed.

The circuit board 3 may include the bonding material 4A (first bonding material) containing a metal element which is disposed on the terminal 10A and the bonding material 4A (second bonding material) containing a metal element which is disposed on the terminal 10B. In this case, the electronic component 2 can be mounted on the terminals 10A and 10B via the bonding materials 4A.

The method for manufacturing the mounting board 1 according to the present embodiment is a method for manufacturing the mounting board 1 by mounting the electronic component 2 on the above-described circuit board 3 to manufacture the mounting board 1, in which the filling material 20 is disposed on the substrate 8, the electronic component 2 is disposed, and then the electronic component 2 may be bonded to the terminal 10 by using the pressurization reflow device 49.

In this case, the same functions and effects as those of the above-described circuit board 3 can be obtained.

The present disclosure is not limited to the embodiments described above. For example, the number and arrangement of terminals of the circuit board are not particularly limited.

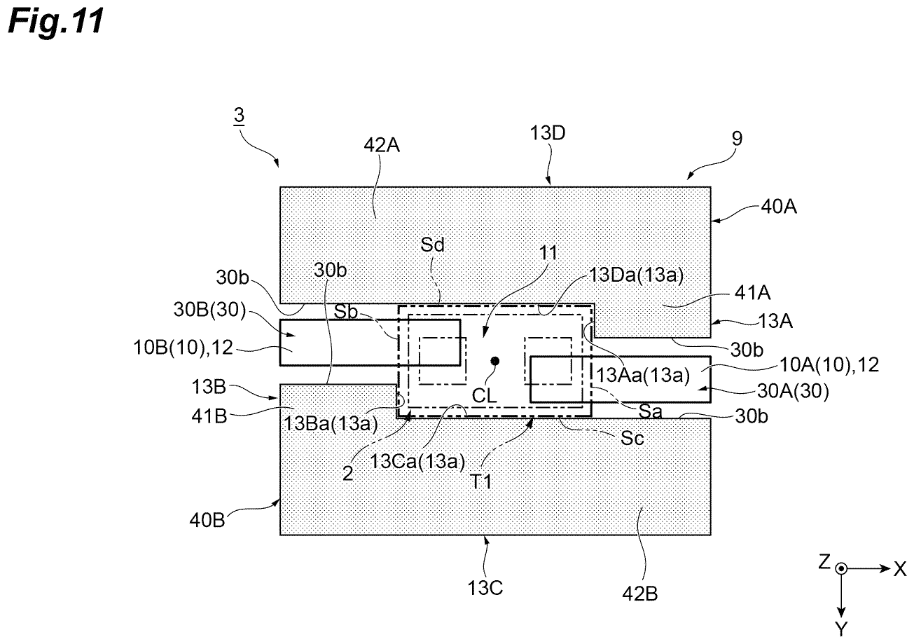

The structure of the wall 9 is not limited to the embodiments described above. For example, a structure illustrated in FIG. 11 may be adopted. The circuit board 3 illustrated in FIG. 11 has the groove portions 30 extending in the X-axis direction, and the terminals 10A and 10B extend in the X-axis direction. In an example of FIG. 11, the groove portion 30A extends toward the positive side in the X-axis direction so as to form the side surface 30b continuous with the inner peripheral surface 13Ca in the wall-frame portion 13A. The groove portion 30B extends toward the negative side in the X-axis direction so as to form the side surface 30b continuous with the inner peripheral surface 13Da in the wall-frame portion 13B. Thereby, the frame 40A has the first side portion 41A extending in a short range in the Y-axis direction on the positive side in the X-axis direction and the second side portion 42A extending long in the X-axis direction on the negative side in the Y-axis direction. The frame 40B has the first side portion 41B extending in a short range in the Y-axis direction on the negative side in the X-axis direction and the second side portion 42B extending long in the X-axis direction on the positive side in the Y-axis direction.

The terminal 10A extends toward the outer peripheral side (the positive side in the X-axis direction) with respect to the short side portion Sa of the reference shape T1 and is disposed in the groove portion 30A. The terminal 10A has a portion disposed on the outer peripheral side from only one short side portion Sa (the short side portion on the positive side in the X-axis direction) of the rectangular reference shape T1. The terminal 10B extends toward the outer peripheral side (the negative side in the X-axis direction) with respect to the short side portion Sb of the reference shape T1 and is disposed in the groove portion 30B. The terminal 10B has a portion disposed on the outer peripheral side from only one short side portion Sb (the short side portion on the negative side in the X-axis direction) of the rectangular reference shape T1.

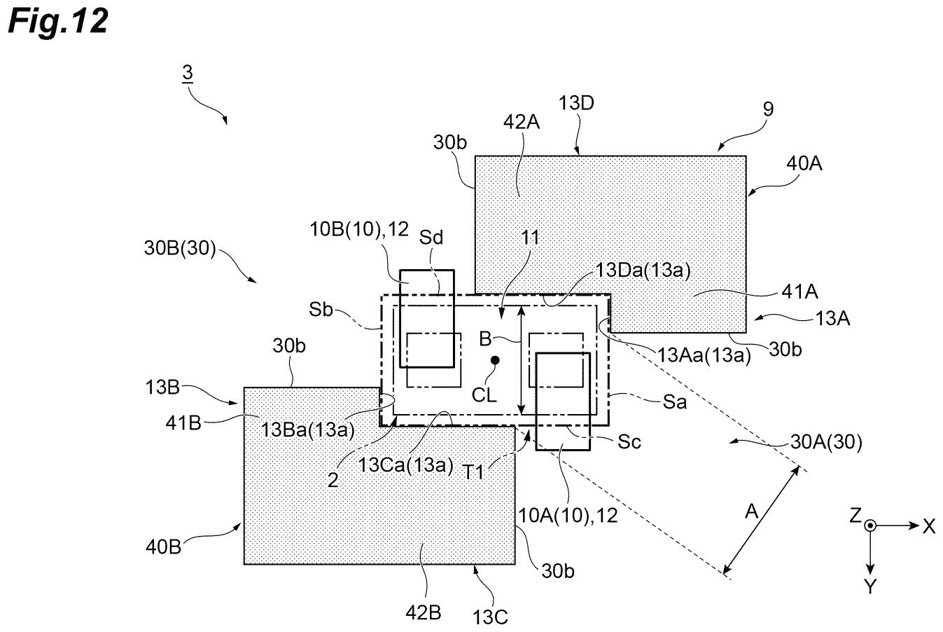

For example, a structure illustrated in FIG. 12 may be adopted. The circuit board 3 illustrated in FIG. 12 has the groove portion 30A having a large size at a corner portion between the wall-frame portions 13A and 13C, and the groove portion 30B having a large size at a corner portion between the wall-frame portions 13B and 13D. The side surface 30b of the groove portion 30A on the wall-frame portion 13A side extends in the X-axis direction at a position on the negative side in the Y-axis direction with respect to the central axis CL. The side surface 30b of the groove portion 30A on the wall-frame portion 13C side extends in the Y-axis direction at a position on the positive side in the X-axis direction with respect to the central axis CL. The side surface 30b of the groove portion 30B on the wall-frame portion 13B side extends in the X-axis direction at a position on the positive side in the Y-axis direction with respect to the central axis CL. The side surface 30b of the groove portion 30B on the wall-frame portion 13D side extends in the Y-axis direction at a position on the negative side in the X-axis direction with respect to the central axis CL. Thereby, the frame 40A includes the first side portion 41A extending in a short range in the Y-axis direction on the positive side in the X-axis direction and the second side portion 42A extending in the X-axis direction on the negative side in the Y-axis direction. The frame 40B includes the first side portion 41B extending in a short range in the Y-axis direction on the negative side in the X-axis direction and the second side portion 42B extending in the X-axis direction on the positive side in the Y-axis direction.

The terminal 10A extends toward the outer peripheral side (the positive side in the Y-axis direction) with respect to the long side portion Sc of the reference shape T1 and is disposed in the groove portion 30A. The terminal 10A has a portion disposed on the outer peripheral side from only one long side portion Sc (the long side portion on the positive side in the Y-axis direction) of the rectangular reference shape T1. The terminal 10B extends toward the outer peripheral side (the negative side in the Y-axis direction) with respect to the long side portion Sd of the reference shape T1 and is disposed in the groove portion 30B. The terminal 10B has a portion disposed on the outer peripheral side from only one long side portion Sd (the long side portion on the negative side in the Y-axis direction) of the rectangular reference shape T1.

Note that, as in an example illustrated in FIG. 12, the minimum aperture dimension A of the groove portion 30 may be larger than the dimension B of the short side of the electronic component 2. However, the aperture dimension A may be equal to or less than the dimension B of the short side by reducing the groove portion 30 in size.

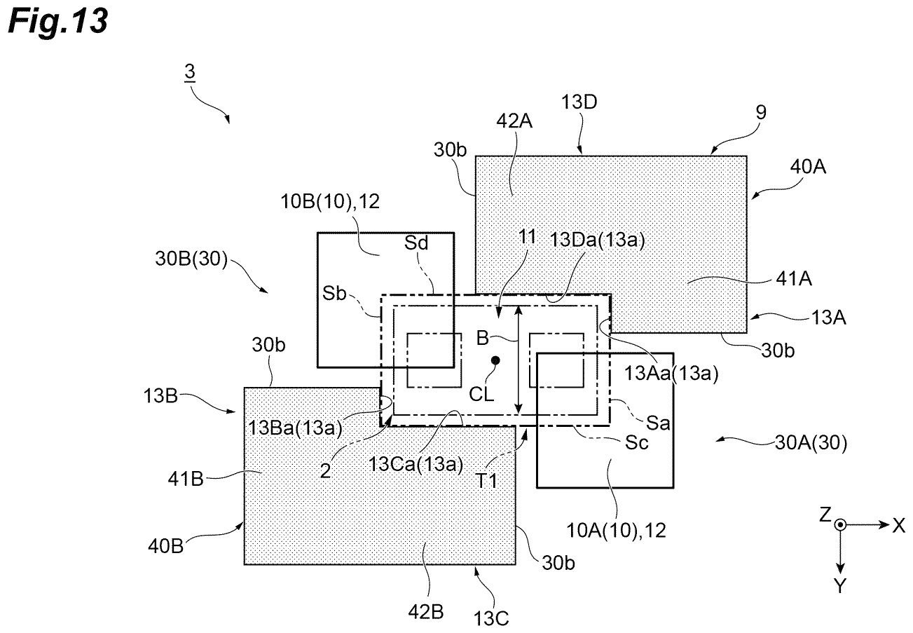

A structure illustrated in FIG. 13 may be employed. In the circuit board 3 illustrated in FIG. 13, the terminals 10A and 10B are wider than those in FIG. 12. The terminal 10A extends toward the outer peripheral side (the positive side in the Y-axis direction) with respect to the long side portion Sc of the reference shape T1, extends toward the outer peripheral side (the positive side in the X-axis direction) with respect to the short side portion Sa, and is disposed in the groove portion 30A. The terminal 10B extends toward the outer peripheral side (the negative side in the Y-axis direction) with respect to the long side portion Sd of the reference shape T1, extends toward the outer peripheral side (the negative side in the X-axis direction) with respect to the short side portion Sb, and is disposed in the groove portion 30B. In this manner, the terminals 10A and 10B may have portions disposed on the outer peripheral side from a plurality of directions with respect to the reference shape T1.

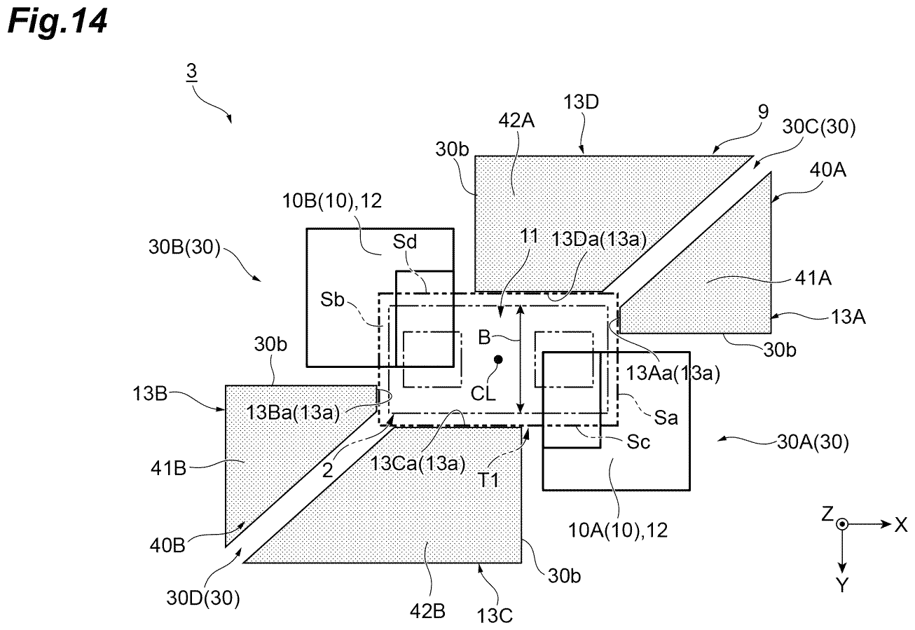

Furthermore, a structure illustrated in FIG. 14 may be employed. In the circuit board 3 illustrated in FIG. 14, as the groove portions 30, the groove portions 30A and 30B (first groove portions) in which the terminals 10A and 10B are disposed and the groove portions 30C and 30D (second groove portions) in which the terminals 10A and 10B are not disposed are formed in the wall 9. In this case, when the excessive filling material 20 is generated by pushing the electronic component 2 into the cavity 11, the excessive filling material can be discharged to the outside of the cavity through the groove portions 30C and 30D. In FIG. 14, with respect to the wall 9 illustrated in FIG. 13, the groove portion 30C having a narrow width is formed at a corner portion between the wall-frame portions 13A and 13D, and the groove portion 30D having a narrow width is formed at a corner portion between the wall-frame portions 13B and 13C.

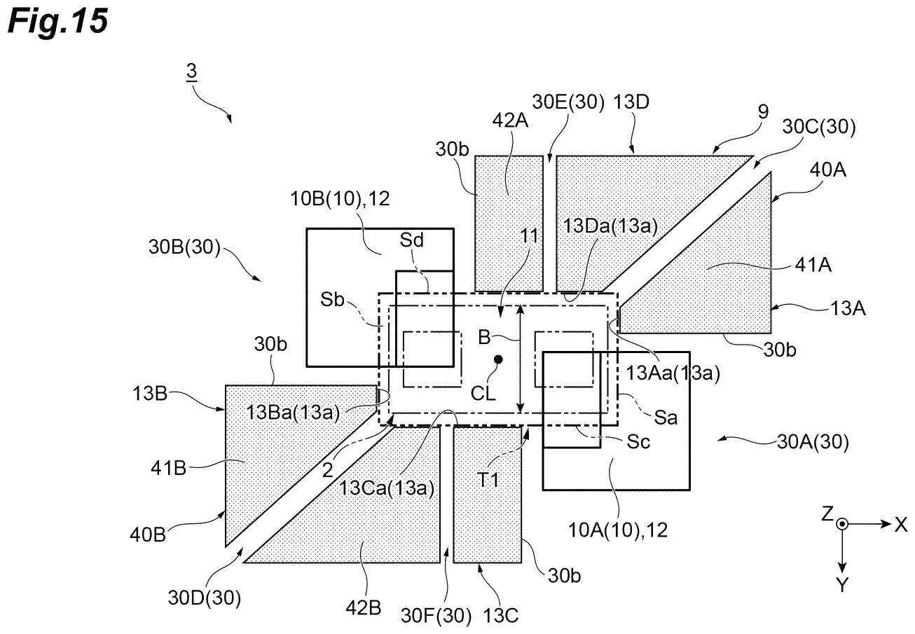

Furthermore, a structure illustrated in FIG. 15 may be employed. In the circuit board 3 illustrated in FIG. 15, with respect to the wall 9 illustrated in FIG. 14, a groove portion 30E having a narrow width extending in the Y-axis direction is formed in the wall-frame portion 13D, and a groove portion 30F having a narrow width extending in the Y-axis direction is formed in the wall-frame portion 13C.

Note that, in the embodiments and modifications described above, both the terminal 10A (first terminal) and the terminal 10B (second terminal) have a portion disposed on the outer peripheral side from the reference shape via the groove portion. However, it is sufficient that at least one terminal of the terminal 10A (first terminal) and the terminal 10B (second terminal) has a portion disposed on the outer peripheral side from the reference shape via the groove portion, and the other terminal may not have a portion disposed on the outer peripheral side from the reference shape.

### Embodiment 1

A circuit board including:
a substrate having a main surface;
a first terminal and a second terminal provided on the main surface of the substrate; and
a wall of an insulating material, the wall provided on the main surface of the substrate, wherein
the wall has at least one groove portion passing through an outer peripheral surface from an inner peripheral surface,
the first and second terminals are disposed in a cavity surrounded by the wall, and
when a rectangular reference shape having a minimum area circumscribing the inner peripheral surface of the wall is set as viewed from a first direction orthogonal to the main surface of the substrate, at least one terminal of the first and second terminals has a portion disposed on an outer peripheral side from the reference shape via the groove portion.

### Embodiment 2

The circuit board according to embodiment 1, wherein
the wall has an L-shaped first frame and an L-shaped second frame, and
the first and second frames are configured to be rotationally symmetric with respect to a central axis of the cavity.

### Embodiment 3

The circuit board according to embodiment 1 or 2, wherein a minimum aperture dimension of the groove portion is equal to or less than a dimension of a short side of an electronic component to be mounted on the first and second terminals.

### Embodiment 4

The circuit board according to any one of embodiments 1 to 3, wherein the at least one terminal has a portion disposed on an outer peripheral side from only one side portion of the rectangular reference shape.

### Embodiment 5

The circuit board according to any one of embodiments 1 to 4, wherein the wall has, as the groove portion, a first groove portion where the at least one terminal is disposed and a second groove portion where the at least one terminal is not disposed.

### Embodiment 6

The circuit board according to any one of embodiments 1 to 5, further including a first bonding material containing a metal element and a second bonding material containing a metal element, the first bonding material disposed on the first terminal and the second bonding material disposed on the second terminal.

### Embodiment 7

A method for manufacturing a mounting board, the method including mounting an electronic component on the circuit board according to any one of embodiments 1 to 6 to manufacture a mounting board, wherein

a filling material is disposed on the substrate, the electronic component is disposed, and then the electronic component is bonded to the first and second terminals by using a pressurization reflow device.

### REFERENCE SIGNS LIST

1 Mounting board
2 Electronic component
3 Circuit board
4A Bonding material
8 Substrate
9 Wall
10A Terminal (first terminal)
10B Terminal (second terminal)
30 Groove portion
30A, 30B Groove portion (first groove portion)
30C, 30D, 30E, 30F Groove portion (second groove portion)
40A Frame (first frame)
40B Frame (second frame)
49 Pressurization reflow device

What is claimed is:

1. A circuit board comprising:
a substrate having a main surface;
a first terminal and a second terminal provided on the main surface of the substrate; and
a wall of an insulating material, the wall provided on the main surface of the substrate, wherein
the wall has at least one groove portion passing through an outer peripheral surface from an inner peripheral surface,
the first and second terminals are disposed in a cavity surrounded by the wall, and
when a rectangular reference shape having a minimum area circumscribing the inner peripheral surface of the wall is set as viewed from a first direction orthogonal to the main surface of the substrate, at least one terminal of the first and second terminals has a portion disposed on an outer peripheral side from the reference shape via the groove portion.

2. The circuit board according to claim 1, wherein
the wall has an L-shaped first frame and an L-shaped second frame, and
the first and second frames are configured to be rotationally symmetric with respect to a central axis of the cavity.

3. The circuit board according to claim 1, wherein a minimum aperture dimension of the groove portion is equal to or less than a dimension of a short side of an electronic component to be mounted on the first and second terminals.

4. The circuit board according to claim 1, wherein the at least one terminal has a portion disposed on an outer peripheral side from only one side portion of the rectangular reference shape.

5. The circuit board according to claim 1, wherein the wall has, as the groove portion, a first groove portion where the at least one terminal is disposed and a second groove portion where the at least one terminal is not disposed.

6. The circuit board according to claim 1, further comprising a first bonding material containing a metal element and a second bonding material containing a metal element, the first bonding material disposed on the first terminal and the second bonding material disposed on the second terminal.

7. A method for manufacturing a mounting board, the method comprising mounting an electronic component on the circuit board according to claim 1 to manufacture a mounting board, wherein
a filling material is disposed on the substrate, the electronic component is disposed, and then the electronic component is bonded to the first and second terminals by using a pressurization reflow device.
